(19) United States
(12) Patent Application Publication
(10) Pub. No.: US 2024/0096741 A1
(43) Pub. Date: Mar. 21, 2024

(54) COOLING SYSTEMS WITH MAIN AND REMOTE COOLING MASSES HAVING INTEGRATED FLEXIBILITY

(71) Applicant: Intel Corporation, Santa Clara, CA (US)

(72) Inventors: Phil GENG, Washougal, WA (US); David SHIA, Portland, OR (US); Ralph V. MIELE, Hillsboro, OR (US); Guixiang TAN, Portland, OR (US); Jimmy CHUANG, Taipei (TW); Sandeep AHUJA, Portland, OR (US); Sanjoy K. SAHA, Portland, OR (US); Jeffory L. SMALLEY, Olympia, WA (US); Mark E. SPRENGER, Tigard, OR (US)

(21) Appl. No.: 18/520,425

(22) Filed: Nov. 27, 2023

(51) Int. Cl. H01L 23/427

(52) U.S. Cl. CPC H01L 23/427

(57) ABSTRACT

An apparatus is described. The apparatus includes a semiconductor chip package, a main cooling mass, a heat pipe and a remote cooling mass. The apparatus further includes: a) a channel in one of the main and remote cooling masses into which the heat pipe is inserted, the channel being wide enough to allow movement of the heat pipe within the channel in response to relative movement of the main and remote cooling masses, wherein, the main cooling mass comprises a chamber with liquid, the heat pipe comprises a fluidic channel that is coupled to the chamber and vapor from the liquid is to be condensed within the heat pipe; b) a flexible region integrated into the heat pipe; and/or, c) a flexible connector into which the heat pipe is inserted.

### BACKGROUND

With the continued demand for higher performance information systems, and with the increasing power consumption of semiconductor chips and/or their packaged solutions in response, engineers are continually seeking ways to improve the manner by which heat is removed from the chips and/or their packaged solutions.

### BRIEF DESCRIPTION OF THE DRAWING

FIG. 1 depicts a remote modular hear sink (RMHS) system;

FIGS. 2a, 2b, 2c, 2d, 2e, 2f and 2g pertain to embodiments for integrating flexibility to a heat pipe/cooling mass interface;

FIGS. 3a, 3b, 3c, 3d, 3e and 3f pertain to embodiments for integrating flexibility to a heat pipe;

FIGS. 4a, 4b and 4c pertain to embodiments of a flexible connector that joins first and second heat pipes;

FIG. 5 shows a data center.

### DETAILED DESCRIPTION

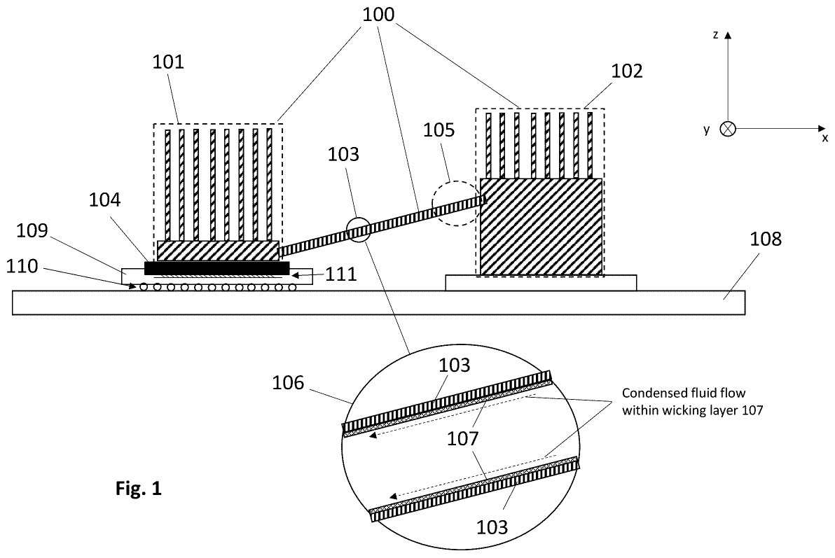

FIG. 1 shows a generic view of a cooling solution 100 that includes a main cooling mass 101 and a remote cooling mass 102 that are coupled with one or more heat pipes 103. One or more high performance semiconductor chips are disposed within a semiconductor chip package 104. The main cooling mass 101 is mechanically and thermally coupled to the semiconductor chip package 104 with low thermal resistance so that heat generated by the semiconductor chip(s) within the chip package 104 transfers from the chip package 104 to the main cooling mass 101. A cooling mass 101, 102 includes a base of solid thermally conductive material. As observed in FIG. 1, a cooling mass can also include thermally conductive fins that emanate from the base (whether fins are present or not depends on the specific cooling mass implementation).

According to an approach referred to as remote modular heat sink (RMHS), the base of the main cooling mass 101 includes an inner chamber with liquid that is coupled to the one or more heat pipes 103. The inner chamber can be implemented as a chamber formed within the base that the one or more heat pipes 103 separately couple to, and/or, can be an extension of the one or more heat pipes 103 that are embedded within the base and run within the base.

Heat that is received by the main cooling mass 101 from the chip package 104 is transferred to the liquid within the chamber, which, in turn, causes the liquid to at least partially vaporize. The one or more heat pipes 103, which are hollow tubes, are fluidically coupled to the chamber within the main cooling mass 101 (there is an open channel between the chamber and the hollow inner region of the pipe(s) 103).

The vapor from the liquid escapes the main cooling mass 101 thereby removing the heat generated by the semiconductor chip(s) from the chip package 104 and main cooling mass 101 assembly. Because the heat pipe(s) 103 are oriented upward as they approach the remote cooling mass 102, and because vapor naturally rises, the vapor travels up the heat pipe(s) toward the remote cooling mass 102 (the one or more heat pipes 103 act as a vapor chamber).

The remote cooling mass 102, which can have a larger base than the main cooling mass 101, sinks the temperature of the ends of the one or more heat pipes 103 that are coupled to the remote cooling mass 102 to a temperature that is cool enough to condense the vapor. Thus, the rising vapor condenses back to liquid within a region 105 of the heat pipe(s) 103 that is typically closer to the remote cooling mass 102. The condensed liquid then flows down the heat pipe(s) 103 back into the liquid chamber within the main cooling mass 101. The process then repeats.

Inset 106 shows a cross section of a heat pipe along its length. As observed in inset 106, the inner surface of a heat pipe 103 includes a “wicking” layer 107 that promotes the flowing of the condensed liquid down the pipe and into the liquid chamber within the main cooling mass 101. In particular, the wicking layer 107 is porous and includes small fluidic channels within the layer 107. Through capillary action (the propensity of a liquid to flow through a narrow opening), the condensed liquid flows through the wicking layer's narrow fluidic channels toward the chamber within the main cooling mass 101.

Unfortunately, the mechanical coupling of the remote cooling mass 102 to the main cooling mass 101 through the heat pipes 103 can induce mechanical reliability problems. Specifically, with the one or more heat pipes 103 being rigidly secured at both ends to both masses 101, 102, movement of the remote cooling mass relative 102 to the main cooling mass 101 can subject the pipe(s) 103 to forces that damage the pipe(s) 103, and/or, damage the assembly that electrically and mechanically couples the chip package 104 to the substrate 108 (such as a printed circuit board).

For example, if the remote cooling mass 102 is anchored to the printed circuit board 108 (and/or the box chassis to which the printed circuit board is mounted) after the heat pipes 103 have been coupled at both ends to both cooling masses 101, 102, the movement of the remote cooling mass 102 can induce forces on the heat pipes 103 that are then transferred to the main cooling mass 101. The main cooling mass 101 and the chip package 104 can then move in response.

The movement of the chip package 104 can damage the frame of a socket 109 that the chip package 104 is plugged into, damage the electrical I/Os 110 between the socket 109 and the printed circuit board 108, and/or, damage the electrical I/Os 111 between the socket 109 and the chip package 104 (e.g., land grid array (LGA) pad fretting). Similar movements and damage(s) can occur in the presence of mechanical shock, particularly if there is a large mass difference between the main 101 and remote 102 masses (kinetic energy imparted to the larger mass could induce, through the heat pipes 103, significant movement to the smaller mass).

A first solution is to incorporate flexibility at the mechanical interface between an end region of a heat pipe and the cooling mass (main or remote) that the end region of the heat pipe is coupled to.

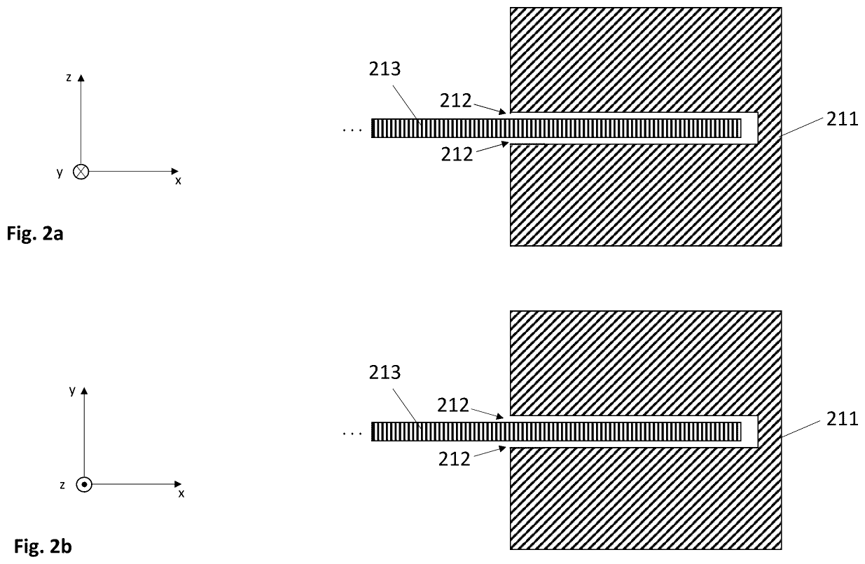

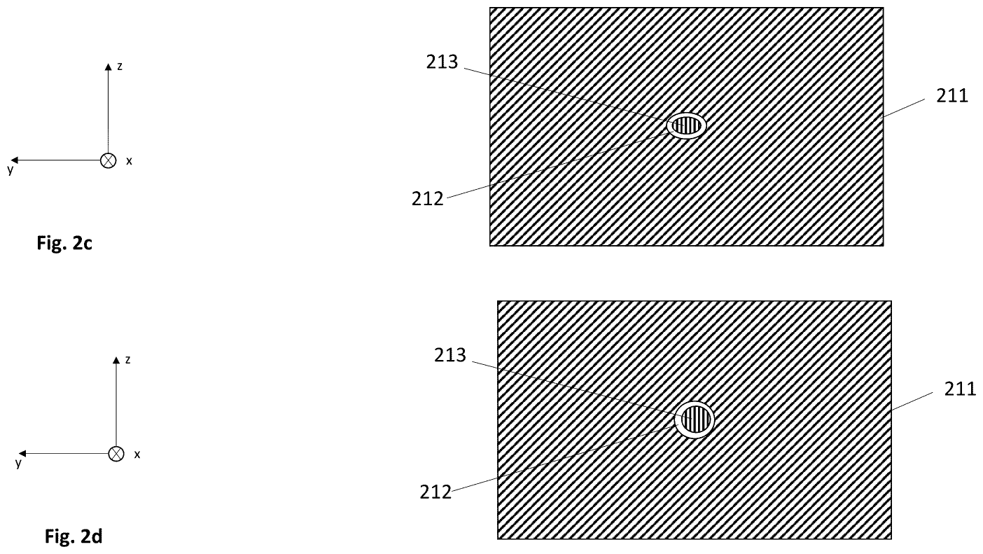

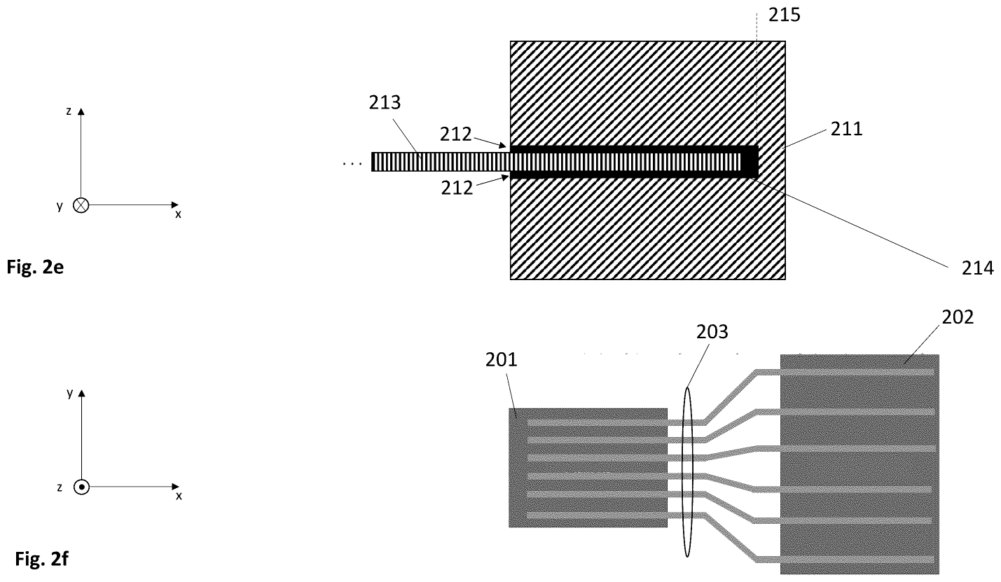

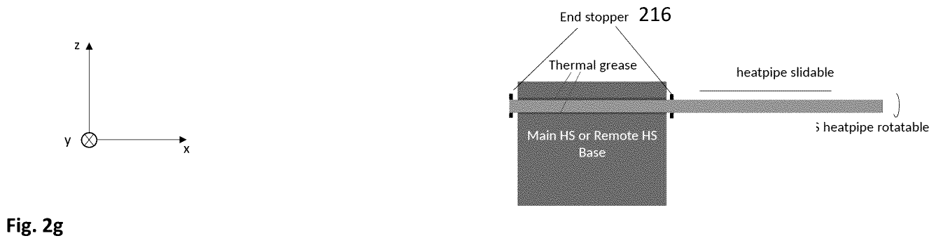

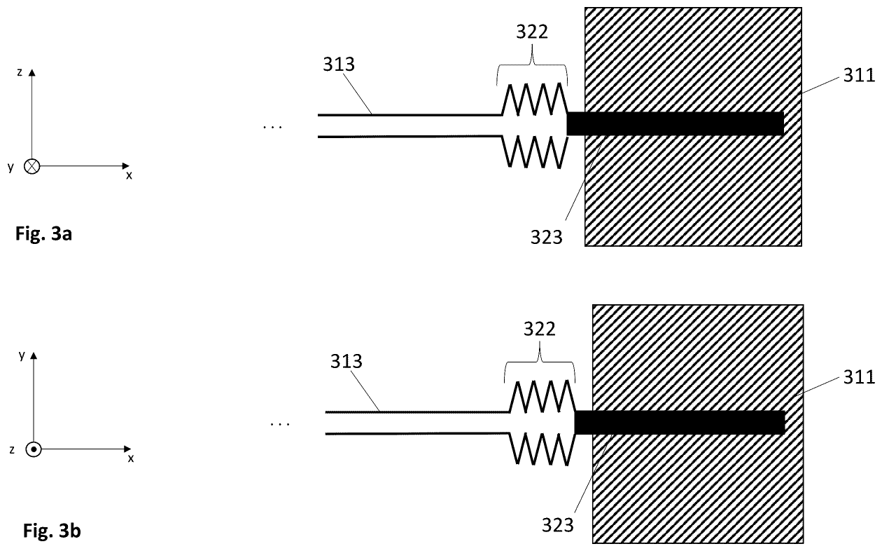

FIGS. 2a though 2c depict a first embodiment. Here, an open channel 212 is formed in the body of the cooling mass 211 to receive the heat pipe 213. The heat pipe 213 is mechanically coupled to the cooling mass 211 by inserting the heat pipe 213 into the channel opening at the face of the cooling mass 211 and sliding the heat pipe 213 deeper into the cooling mass 211 along the channel 212.

Importantly, the dimensions of the channel 212 are larger than the corresponding dimensions of the heat pipe 213. For example, if the cross section of the heat pipe 213 is elliptical, as observed in FIG. 2c, the dimensions of the major and minor axes of the channel 212 are larger than the corresponding major and minor axes of the heat pipe 213.

The wider channel 212 allows the heat pipe 213 to move relative the cooling mass 211, which, in turn, can alleviate/reduce (“absorb”) mechanical forces applied to the heat pipe 213 by the movement of the cooling mass 211, and/or, alleviate/reduce mechanical forces applied to the cooling mass 211 by movement of the heat pipe 213.

As observed in the particular example of FIGS. 2a through 2c, the heat pipe 213 is allowed to move relative to the cooling mass 211 along: 1) the x and z axes (FIG. 2a); the x and y axes (FIG. 2b); and, 3) the y and z axes (FIG. 2c). Additionally, the heat pipe 213 can rotate about the x axis at least until the projection of the heat pipe's major axis along the z axis equals the channel's minor axis. If the heat pipe 213 and channel 212 are made circular, as observed in FIG. 2d, the rotation of the heat pipe 213 can be unlimited.

Thus, for example, if the mechanical interface between the heat pipe 213 and the remote cooling mass adopts the approach of FIGS. 2a, 2b and 2c or 2d, and movement is imparted to the remote cooling mass as a consequence of its being anchored or in response to mechanical shock, such movement is at least partially “absorbed” by the spacings between the heat pipe 213 and the channel within the remote cooling mass.

Moreover, even if some movement or force is imparted to the heat pipe 213 by the movement of the remote cooling mass, if the design of FIGS. 2a, 2b and 2c or d2 is also incorporated at the mechanical interface between the heat pipe 213 and the main cooling mass, such force/movement (including rotational force/movement) will be at least partially absorbed by the spacing between the heat pipe 213 and the main cooling mass such that little/no movement/rotation is induced in the main cooling mass.

Air spacings between the heat pipe 213 and cooling mass 211 can increase the thermal resistance between the heat pipe 213 and cooling mass 211. Therefore, in order to keep the thermal resistance between the heat pipe 213 and cooling mass 211 low, as observed in FIG. 2e, the spacing between the heat pipe 213 and the cooling mass 211 can be filled with a soft thermal interface material 214, such as a grease, gel or paste having low thermal resistance. Introducing such material 214 at least in the space between the heat pipe 213 and the remote cooling mass will allow the remote cooling mass to behave as a true heat sink for the heat pipe 213.

FIG. 2f shows a top down view of a complete solution in which multiple heat pipes 203 are coupled to both the main cooling mass 201 and the remote cooling mass 202 by way of openings in the masses that, as described just above, have larger dimensions than the pipes 203 (FIG. 2f is not drawn to scale and does not depict the different dimensions with particularity).

In the particular embodiments of FIGS. 2a through 2f, the channel in a cooling mass physically terminates within the cooling mass resulting in a “hard stop” wall 215 (labeled in FIG. 2e) beyond which the pipe 213 is not capable of moving along the x axis (the pipe 213 will bump against the wall 215).

With this particular approach, referring to FIG. 2f, flexibility of heat pipe movement along the x axis is possible if the length of the heat pipes 213 along the x axis are designed to be less than the distance along the x axis between the respective hard stop walls of the main and remote cooling masses 201, 202.

In another approach, as observed in FIG. 2g, the channel within a cooling mass can run completely through the cooling mass, in which case, a hard stop wall as described just above does not exist. To prevent unlimited movement of the heat pipe along the x axis, stoppers 216 are fixed to the heat pipe on both sides of the cooling mass which limits the movement of the heat pipe along the x axis to the difference between the length of the cooling mass along the x axis and the distance between the stoppers 216 along the x axis.

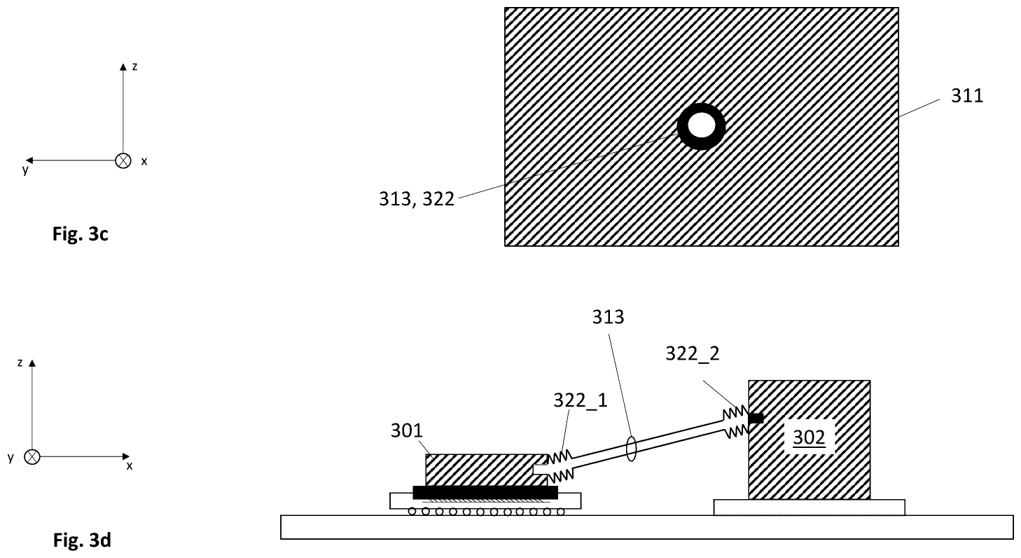

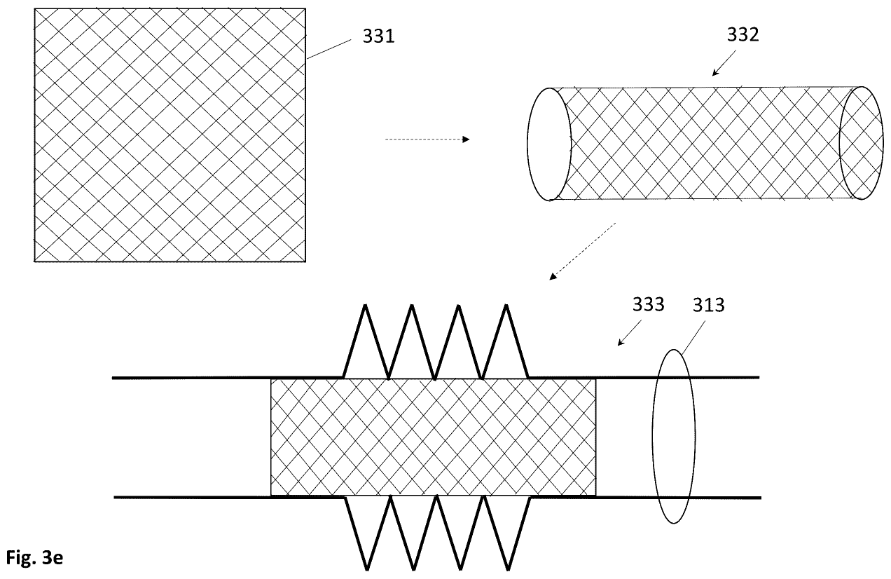

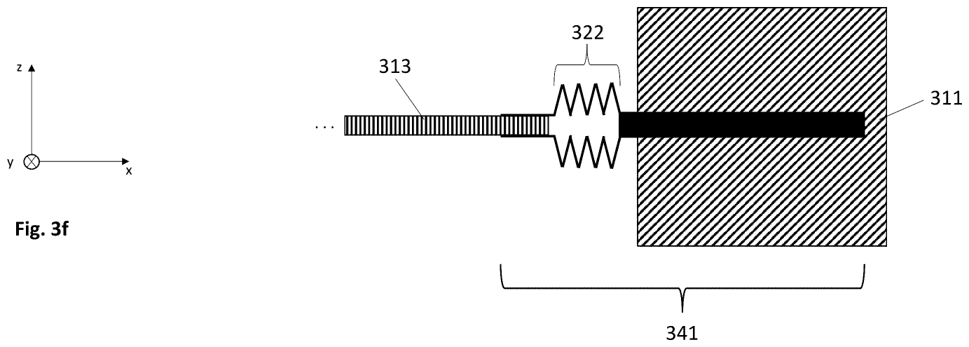

FIGS. 3a through 3c pertain to another design in which flexibility is imparted at the interface between a heat pipe 313 and a cooling mass 311 by forming the heat pipe 313 with an integrated flexible region 322 (e.g., a corrugated region 322) near the end of the heat pipe 313 that mechanically couples with the cooling mass 311. The flexible region 322 permits the heat pipe 313 to be compressed, expanded, rotated and/or bent in any direction relative to the cooling mass 311.

According to the particular embodiment of FIGS. 3a through 3c, the heat pipe 313 has a solid end that is press fit into a corresponding opening in the cooling mass 311. With a sufficiently tight press fit, the heat pipe 313 is rigidly secured to the cooling mass 311. Thermal interface material (not shown) can be applied between the solid portion 323 of the heat pipe 313 and the cooling mass 311 to reduce the thermal resistance between the heat pipe 313 and the cooling mass 311.

FIG. 3d shows a complete solution in which the heat pipe 313 is formed with flexible regions 322_1, 322_2 near both ends of the heat pipe 313 so that there is flexibility imparted to the heat pipe's mechanical connections to both the main cooling mass 301 and the remote cooling mass 302. Notably, the flexible region 322_1 that is coupled to the main cooling mass 301 has an open channel to fluidically couple the pipe's hollow inner space to the liquid chamber within the main cooling mass 301. By contrast, the flexible region 322_2 that is coupled to the remote cooling mass can have a solid end that is physically inserted into the remote cooling mass 302. In other embodiments, a single flexible region can be formed in the pipe (e.g., near the remote cooling mass 302, near the main cooling mass 301, toward the middle of the heat pipe), e.g., to reduce heat pipe manufacturing complexity.

Still other embodiments may add additional flexible regions to the embodiment of FIG. 3d (e.g., closer to the middle of the heat pipe 313), e.g., to impart more flexibility into the system. Other embodiments can have one or more flexible regions formed in the heat pipe closer to the middle of the heat pipe rather than towards the ends of the heat pipe. In this case, the heat pipe ends can be rigidly fixed to the cooling masses, or, can be flexibly connected to the cooling masses as described above with respect to FIGS. 2a through 2g.

FIG. 3e shows a method for the forming of a wicking layer within a heat pipe 313 having an integrated flexible region as described above. As observed in FIG. 3e a sheet 331 of (e.g., metal) wire mesh is formed with the mesh wires oriented at angles with respect to the edges of the sheet 331 (as observed in FIG. 3e, both sets of parallel wires are orthogonal to one another while being oriented at approximately 45° with respect to the sheet edges). The sheet 313 is then rolled 332 into a tube having a diameter that is ideally approximately the same as the inner diameter of the heat pipe. The rolled mesh sheet is then inserted 333 into the heat pipe 313 and affixed to the inner surface of the heat pipe 313 (e.g., by being soldered at certain points within the pipe).

Notably, the planar surface of the rolled sheet 331 combined with the capillaries formed by the openings in the mesh allows for the condensed liquid to easily flow along the mesh through capillary action, including along the flexible region 342 (FIG. 3e is not drawn to scale as the mesh wires can be placed closer together to form narrower capillaries). Additionally, because of the angled orientation of the mesh wires with respect to the axis of the pipe 343, the mesh easily compresses/expands/bends/rotates in response to forces that are applied to the pipe 313. Thus, the wire mesh is able to deform along with the flexible region 342 while promoting the flow of liquid back to the main cooling mass.

In an alternate approach or combined approach, the wicking layer is formed by sintering. Here, particles (e.g., of a powder) are coated on the inner surface of the heat pipe with a filler or binder (e.g., having epoxy like characteristics). Under high pressure and/or temperature, the particles fuse together and the filler/binder is removed. The narrow spaces between particles form the narrow openings for the wicking layer's capillary action. The porosity of the resulting layer also contributes to its elasticity, which, in turn, allows the layer to compress/expand/bend/rotate in response to forces that are applied to the heat pipe.

FIG. 3f shows another embodiment, to be compared with FIG. 3a, in which a thermally conductive connector 341 having a flexible region 322 mechanically couples the heat pipe 313 to a cooling mass 311. If the cooling mass is a remote cooling mass, the connector 341 can have a solid end that press fits into an opening in the remote cooling mass 311. The connector is tube-like on the opposite end. The heat pipe 313 press fits into the open tube end to connect to the connector 341. For RMHS systems, if the cooling mass is the main cooling mass, the end of the connector that press fits into the cooling mass opening should be hollow to create the fluidic channel between the main cooling mass's liquid chamber and the fluidic channel within the pipe 313.

With the connector 341 being, e.g., composed of metal, and therefore thermally conductive, there is low thermal resistance between the cooling mass 311 and the heat pipe 313. The thermal interface material can be applied in the spaces between the end of the connector 341 that is coupled to the heat pipe 313, and/or the end of the heat pipe 313 that is connected to the cooling mass 311 to further reduce the thermal resistance of the overall connection.

The connector of FIG. 3f can be used at both ends of the heat pipe 313 to effect a total solution like that of FIG. 3d but where the flexible regions 322_1, 322_2 are formed with connectors as observed in FIG. 3f (with the connector that is connected to the main cooling mass 301 having a hollow end that connects to the main cooling mass 301, and, e.g., the connector that is connected to the remote cooling mass 302 having a solid end that connects to the remote cooling mass 302). In other embodiments, the heat pipe 313 can be formed to have an integrated flexible region at one end and a connector having a flexible region at the other end.

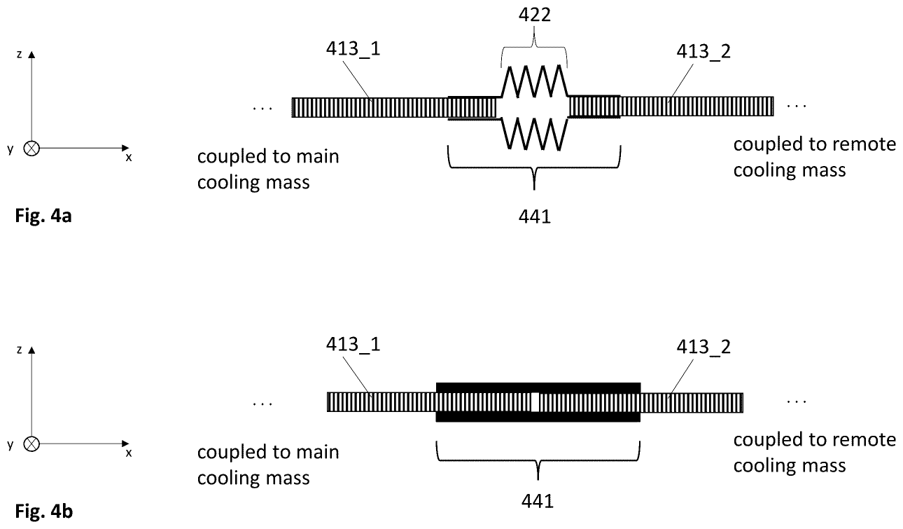

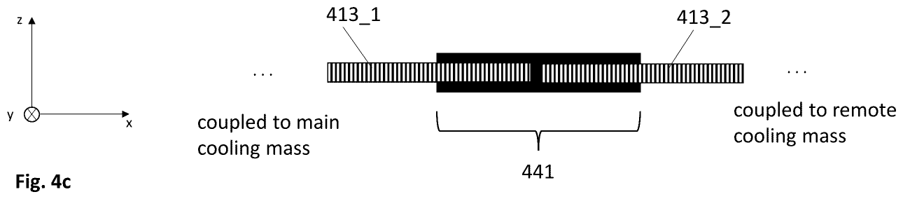

FIGS. 4a through 4c pertain to yet other embodiments in which flexibility is induced into the system by coupling a first heat pipe 413_1 to one of the cooling masses (e.g., the main cooling mass), coupling a second heat pipe 413_2 to the other of the cooling masses (e.g., the remote cooling mass), and mechanically coupling the pair of heat pipes 413_1, 413_2 together with a flexible connector 441.

According to a first embodiment, as observed in FIG. 4a, the connector 441 is in the shape of a tube (e.g., a sleeve) that includes a flexible region 421. The respective ends of the two different heat pipes 413_1, 413_2 are inserted into opposite ends of the connector 441. A wicking layer that runs along the inner surface of the pipes 413_1, 413_2 and through the connector 441 can be formed with a mesh sheet according the teachings provided above with respect to FIG. 3e, and/or with sintering as described above.

If the connector 441 is made of material having a low thermal resistance (e.g., metal), the connection formed by the connector 441 should have low thermal resistance. The thermal resistance of the connection can be even further lowered by applying thermal interface material in the spaces between one of the heat pipes 413_1 and the connector 441 and/or the other of the heat pipes 413_2 and the connector 441. In various embodiments, the connector 441 is placed closer to the remote cooling mass so that condensation mostly occurs in the heat pipe 413_1 that is coupled to the main cooling mass so that any thermal interface material applied within the connector does not interfere with the flow of condensed fluid back to the main cooling mass (e.g., if thermal interface material is applied to the space within the connector between the two heat pipes).

In other embodiments, observed in FIG. 4b, the connector 441 is composed of elastic material and need not have a specially formed (e.g., corrugated) flexible region (the connector material itself is flexible). In certain ones of these embodiments, the connector material has high thermal resistance (e.g., rubber, plastic, polymer, graphene, etc.). In this case, the inner surface of the connector 441 can be coated with thermal interface material to reduce the thermal resistance between the two heat pipes 413_1, 413_2.

Again, a wicking layer that runs along the inner surface of the pipes 413_1, 413_2 and through the connector 441 can be formed with mesh wiring according to the teachings provided above with respect to FIG. 3e, and/or with sintering as described above. Also again, in various embodiments, the connector 441 is placed closer to the remote cooling mass so that condensation mostly occurs in the heat pipe 413_1 that is coupled to the main cooling mass so that any thermal interface material applied within the connector does not interfere with the flow of condensed fluid back to the main cooling mass.

In still other approaches that use the connectors of FIGS. 4a and 4b, if the connector is placed closer to the remote cooling mass and condensation is designed to occur mainly in the heat pipe 413_1 that is coupled to the main cooling mass, only the heat pipe 413_1 that is coupled to the main cooling mass needs to be hollow and have a wicking layer (the heat pipe 413_2 that is closer to the remote cooling mass need not be hollow and need not have a wicking layer).

FIG. 4c shows another connector that can be used with the approach described immediately above. Here, a fluidic channel does not exist through the connector 441 because connector material is located between both heat pipes 413_1, 413_2. If the connector 441 is composed of a thermally conductive material having some hardness, such as a metal, the connector 411 can exhibit good thermal conductivity between the two pipes 413_1, 413_2 (e.g., which can be enhanced with thermal interface material between the pipes 413_1, 413_2 and the connector 441).

Moreover, the connector 441 can exhibit sufficient flexibility for various applications if the connector material is sufficiently thin (e.g., both its tube walls and the inner wall that separates the two pipes 413_1, 413_2). As described above, for RMHS systems, the connector 441 can be placed closer to the remote cooling mass so that the vaporization occurs in the heat pipe 413_1 that is coupled to the main cooling mass.

If the connector 441 is composed of material that is flexible but exhibits poor thermal conductivity (e.g., rubber, plastic, polymer, graphene, etc.). Again, for RMHS systems, the connector 441 can be placed closer to the remote cooling mass so that the vaporization occurs in the heat pipe 413_1 that is coupled to the main cooling mass.

Notably, the solutions represented by any of FIGS. 2a through 2g, FIGS. 3a through 3f, and FIGS. 4a through 4c can also be applied to extended volume air cooling (EVAC) systems rather than RMHS systems. In the case of an EVAC system, referring briefly back to FIG. 1, fin structures typically emanate from the main cooling mass 101 and the remote cooling mass 102. The heat that is received by the main cooling mass 101 transfers to both the fins that emanate from the main cooling mass 101 and the fins that emanate from the remote cooling mass 102.

The heat then transfers from the main and remote fins to the surrounding air ambient which effectively removes the heat generated by the chips within the chip package 104 from the system. As is known in the art, the heat removal capacity of a finned cooling system improves with the increased surface area between the fins and the air ambient. Thus, the remote thermal mass 102 essentially “adds” fins to the overall solution thereby improving its thermal transfer efficiency to the ambient air.

When applying any of these solutions to an EVAC system, the heat pipes 413_1, 413_2 need not be hollow or include a wicking layer.

Notably, a single cooling apparatus, whether an RMHS cooling system, an EVAC cooling system or both (an example of the latter being an RMHS cooling system where the main and remote cooling masses have fins emanating therefrom), can include multiple ones of the teachings above. For example, a single cooling system can include: 1) a channel in a cooling mass into which a heat pipe is inserted that allows movement of the heat pipe in response to relative movement of the main and remote cooling masses; 2) a heat pipe having an integrated flexible element; and, 3) a flexible connector that is connected to a heat pipe. Other embodiments can include two of 1), 2) and 3) above.

In various embodiments the remote cooling mass need not be mounted to the same printed circuit board that the main cooling mass's mechanical assembly is mounted to. For example, the remote cooling mass can be coupled to a system ceiling/lid that resides above the main cooling mass and faces the printed circuit board.

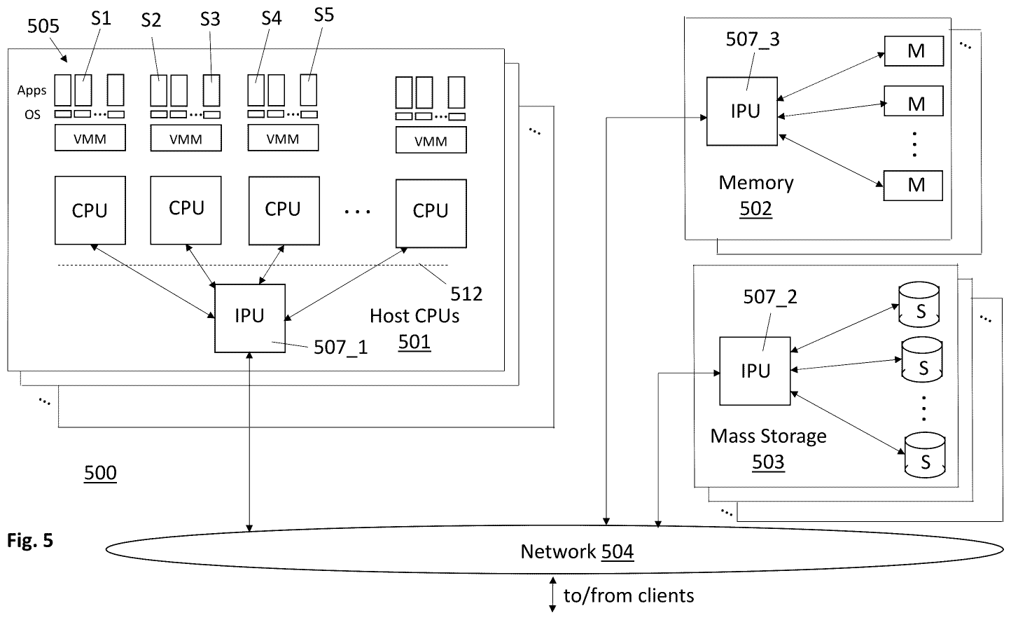

FIG. 5 shows a new, emerging data center environment in which “infrastructure” tasks are offloaded from traditional general purpose “host” CPUs (where application software programs are executed) to an infrastructure processing unit (IPU) or data processing unit (DPU) any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.). Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of a micro-service application.

In order to support the network sessions and/or the applications' functionality, however, certain underlying computationally intensive and/or trafficking intensive functions (“infrastructure” functions) are performed.

Examples of infrastructure functions include routing layer functions (e.g., IP routing), transport layer protocol functions (e.g., TCP), encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators.

As such, as observed in FIG. 5, the infrastructure functions are being migrated to an infrastructure processing unit (IPU) 507. FIG. 5 depicts an exemplary data center environment 500 that integrates IPUs 507 to offload infrastructure functions from the host CPUs 504 as described above.

As observed in FIG. 5, the exemplary data center environment 500 includes pools 501 of CPU units that execute the end-function application software programs 505 that are typically invoked by remotely calling clients. The data center also includes separate memory pools 502 and mass storage pools 505 to assist the executing applications. The CPU, memory storage and mass storage pools 501, 502, 503 are respectively coupled by one or more networks 504.

Notably, each pool 501, 502, 503 has an IPU 507_1, 507_2, 507_3 on its front end or network side. Here, each IPU 507 performs pre-configured infrastructure functions on the inbound (request) packets it receives from the network 504 before delivering the requests to its respective pool's end function (e.g., executing application software in the case of the CPU pool 501, memory in the case of memory pool 502 and storage in the case of mass storage pool 503).

As the end functions send certain communications into the network 504, the IPU 507 performs pre-configured infrastructure functions on the outbound communications before transmitting them into the network 504. The communication 512 between the IPU 507_1 and the CPUs in the CPU pool 501 can transpire through a network (e.g., a multi-nodal hop Ethernet network) and/or more direct channels (e.g., point-to-point links) such as Compute Express Link (CXL), Advanced Extensible Interface (AXI), Open Coherent Accelerator Processor Interface (OpenCAPI), Gen-Z, etc.

Depending on implementation, one or more CPU pools 501, memory pools 502, mass storage pools 503 and network 504 can exist within a single chassis, e.g., as a traditional rack mounted computing system (e.g., server computer). In a disaggregated computing system implementation, one or more CPU pools 501, memory pools 502, and mass storage pools 503 are separate rack mountable units (e.g., rack mountable CPU units, rack mountable memory units (M), rack mountable mass storage units (S)).

In various embodiments, the software platform on which the applications 505 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

Notably, semiconductor chips that operate within a data center, such as the data center, or that operate within a stand alone computer system (e.g., a traditional server computer or desktop computer) can be cooled according to the teachings described above with respect to FIGS. 2a-g, 3a-f and 4a-c. Thus, for example, the semiconductor chip(s) within a chip package that is coupled to a main cooling mass can be any of, for example, multicore CPU processor, a graphics processing unit (GPU) processor, a memory module (e.g., having stacked memory chips), a customized accelerator chip (e.g., that implements a neural network, artificial intelligence inferencing, artificial intelligence machine learning, etc.).

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable storage medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a semiconductor chip package;
a main cooling mass coupled to the semiconductor chip package;
a heat pipe coupled to the main cooling mass; and,
a remote cooling mass coupled to the heat pipe to sink the heat pipe's temperature, the apparatus further comprising:
a) a channel in one of the main and remote cooling masses into which the heat pipe is inserted, the channel being wide enough to allow movement of the heat pipe within the channel in response to relative movement of the main and remote cooling masses, wherein, the main cooling mass comprises a chamber with liquid, the heat pipe comprises a fluidic channel that is coupled to the chamber and vapor from the liquid is to be condensed within the heat pipe;
b) a flexible region integrated into the heat pipe; and/or,
c) a flexible connector into which the heat pipe is inserted.

2. The apparatus of claim 1 wherein the apparatus comprises a) above and the apparatus further comprises another channel in the other of the main and remote cooling masses into which the heat pipe is inserted, the channel being wide enough to allow movement of the heat pipe within the channel in response to the relative movement of the main and remote cooling masses.

3. The apparatus of claim 1 wherein the apparatus comprises a) above and the channel runs through opposite sides of the one cooling mass.

4. The apparatus of claim 1 wherein the apparatus comprises b) above and the flexible region comprises a corrugated surface of the heat pipe.

5. The apparatus of claim 1 wherein the apparatus comprises b) above and the flexible region resides along the heat pipe closer to one of the cooling masses than the other of the cooling masses.

6. The apparatus of claim 1 wherein the apparatus comprises b) above and the apparatus further comprises a wicking layer within the heat pipe's fluidic channel that runs along the flexible region.

7. The apparatus of claim 1 wherein the apparatus comprises c) above and the flexible connector is located closer to one of the cooling masses than the other of the cooling masses.

8. The apparatus of claim 1 wherein the main cooling mass, the remote cooling mass and the heat pipe are components of a remote modular heat sink (RMHS) system.

9. The apparatus of claim 1 wherein the main cooling mass, the remote cooling mass and the heat pipe are components of an extended volume air cooling (EVAC) system.

10. An apparatus, comprising:
a heat pipe to be coupled between a main cooling mass and a remote cooling mass, the heat comprising an integrated flexible region to allow movement of the heat pipe in response to relative movement of the main cooling mass and the remote cooling mass.

11. The apparatus of claim 10 wherein the heat pipe comprises fluidic channel.

12. The apparatus of claim 11 wherein the heat pipe comprises a wicking layer within the fluidic channel that runs along the flexible region.

13. The apparatus of claim 12 wherein the wicking layer comprises a mesh sheet having sets of orthogonal wires that are neither parallel nor orthogonal to an axis that the fluidic channel runs along.

14. The apparatus of claim 12 wherein the wicking layer comprises a sintered layer.

15. The apparatus of claim 10 wherein the integrated flexible region comprises a corrugated region of the heat pipe.

16. An apparatus, comprising:
a flexible connector having an opening to receive at least one heat pipe between a main cooling mass and a remote cooling mass.

17. The apparatus of claim 16 wherein the flexible connector is to be coupled to one of the main cooling mass and the remote cooling mass at an end of the flexible connector that is opposite the opening.

18. The apparatus of claim 16 wherein the flexible connector comprises a flexible region integrated into the flexible connector.

19. The apparatus of claim 18 wherein the flexible connector is comprised of metal.

20. The apparatus of claim 18 wherein the flexible connector is selected from the group consisting of:
rubber;
plastic;
polymer;
graphene.
